(19) United States
(12) Patent Application Publication
(10) Pub. No.: US 2007/0126433 A1
(43) Pub. Date: Jun. 7, 2007

(54) Permeable Moisture Sensor for Concrete, and Other Moisture Sensors, Moisture Sensing Methods and Construction Methods

(76) Inventors: Theophanis Theophanous, Blacksburg, VA (US); John J. Lesko, Blacksburg, VA (US); Scott W. Case, Blacksburg, VA (US)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 11/421,887

(22) Filed: Jun. 2, 2006

Related U.S. Application Data
(60) Provisional application No. 60/686,937, filed on Jun. 3, 2005.

(51) Int. Cl. G01R 27/26

(52) U.S. Cl. 324/690

(57) ABSTRACT

Non-invasive moisture-sensing within concrete (such as concrete buildings, bridges, etc.) or a polymeric material may be accomplished by a capacitor structure comprising a porous material built inside the concrete or polymeric material. The capacitance measurements change based on the amount of moisture in the porous material. Moisture-sensing can be monitored remotely (including for submerged and other structures), relatively non-invasively, and in a repeatable and reversible fashion without intermediate conditioning or resting.

### RELATED APPLICATION

This application claims benefit of U.S. Provisional Application Ser. No. 60/686,937 filed Jun. 3, 2005 titled “Permeable moisture sensor for concrete.”

### STATEMENT REGARDING FEDERAL FUNDING

This invention was federally funded by the Federal Highway Administration, grant number VTRC #M-02-006.

### FIELD OF THE INVENTION

This invention relates to point moisture sensing, particularly to moisture sensing within a structure and to moisture sensing which may be performed remotely from where the moisture is present.

### BACKGROUND OF THE INVENTION

For measuring moisture in various applications, certain principles have been conventionally known for measuring capacitance (such as by making bulk measurements of capacitance) from which moisture content is inferred. Capacitance sensors for bulk measurements of concrete have been commonplace in the industry and simply rely on the placement of the electrodes on the surface of the concrete or placement within the concrete before or after curing. These electrodes for bulk capacitance measurements establish a field of varying special strength leading to integrated bulk measurement of capacitance. Internal electrodes in such bulk-measurement conventional systems impede moisture transport.

There also have been other humidity and moisture sensors which rely on sensing capacitance with other media that collect water and demonstrate a selective moisture content. However, it is unclear how the combination of capacitance and resistance across the sensor are interpreted and calibrated to yield the moisture content measured.

The following are mentioned, as background.

U.S. Pat. No. 4,288,742 issued Sep. 8, 1981 to Walsh for “Electrical soil moisture sensor.”

U.S. Pat. No. 4,540,936 issued Sep. 10, 1985 to Walsh for “Soil moisture sensor.”

U.S. Pat. No. 4,657,039 issued Apr. 14, 1987 to Bireley, et al. for “Moisture sensor.”

U.S. Pat. No. 4,683,904 issued Aug. 4, 1987 to Iltis for “Moisture sensor.”

U.S. Pat. No. 5,590,976 issued Jan. 7, 1997 to Kilheffer et al. (Akzo Nobel Asphalt Applications, Inc.) for “Mobile paving system using an aggregate moisture sensor and method of operation.”

U.S. Pat. No. 5,859,536 issued Jan. 12, 1999 to Stockton for “Moisture sensor having low sensitivity to conductance changes.”

U.S. Pat. No. 6,756,793 issued Jun. 29, 2004 to Hirono, et al. (Matsushita Electric Works, Ltd.) for “Capacitance type moisture sensor and method of producing the same” especially mentioned for sensing moisture in a garbage disposal apparatus.

U.S. Pat. No. 7,037,554 issued May 2, 2006 to Tao et al. (Mississippi State Univ.) for “Moisture sensor based on evanescent wave light scattering by porous sol-gel silica coating” discloses that a porous sol-gel silica polymer is coated on an optical fiber core that forms the transducer of an optical fiber moisture sensor. The sensor is said to be useable to sense moisture content in air, soil, concrete and gas streams.

However, there have been limitations in conventional moisture-sensing technology. Invasiveness into the material to be measured has been one limitation. Feasibility of operations in submerged conditions has been another limitation.

### SUMMARY OF THE INVENTION

The invention provides new devices and methods based upon the principles of measuring capacitance to infer moisture content, where capacitance measurements are made of a material (such as, e.g., concrete, polymeric material, etc.) in new ways. Uniquely, inventive sensors and methods are capable of making point (rather than bulk) measurements of capacitance. Also, advantageously inventive sensors and methods may be virtually non-invasive. Advantageously, an inventive porous sensor due to its porous nature may have a minimal effect on moisture transport within concrete where the sensor is placed. Moreover, in the invention, electrical measurements may be completed in a more rigorous manner than in conventional moisture sensors, allowing for an opportunity to more fully interpret the resistance and capacitance information sensed by the inventive sensors in a repeatable and reversible manner, without intermediate conditioning or resting. The invention also provides for the use of impedance spectroscopy, which may be used to better understand the state of moisture (free versus bound) in the material (e.g., concrete, etc.) under measurement, as well as the presence of other chemical species that contribute to the measured signal.

In one preferred embodiment the invention provides a method of constructing a moisture sensor, comprising: into concrete or into a polymeric material that is to be measured for moisture, constructing a capacitor structure comprising a porous material (such as, e.g., a capacitor structure constructing step performed before the concrete is fully formed; a capacitor structure constructing step performed after the concrete is formed; a constructing step that includes providing a quantity of cement paste, a first electrode (such as, e.g., an electrode comprising a stainless steel wire mesh) and a second electrode (such as, e.g., an electrode comprising a stainless steel wire mesh) disposed together form a capacitor structure; etc.); such as, e.g., inventive construction methods comprising: to the capacitor structure, connecting a read-out device where capacitance measures for the capacitor structure are readable; inventive construction methods including connecting a signal-measuring device to the capacitor structure, and connecting a read-out device to the signal-measuring device; etc.

The invention in another preferred embodiment provides a method of sensing moisture in a concrete material or a polymeric material, comprising: in the concrete material or the polymeric material, making at least one point measurement of capacitance; such as, e.g., inventive moisture sensing methods including making the least one point measurement of capacitance via a capacitor (such as, e.g., via a capacitor within concrete that is remote from where the capacitance measurement is read; via a capacitor comprising a pair of stainless steel wire meshes; etc.) comprising a porous material, said capacitor being disposed within the concrete or the polymeric material; inventive moisture sensing methods wherein the point capacitance measurement is electrically transmitted to a remote device; inventive moisture sensing methods including expressing the point capacitance measurement as an electrical signal and transmitting the electrical signal to a read-out device; etc. In the inventive moisture sensing methods, the concrete material or the polymeric material being sensed for moisture may be submerged.

In a further preferred embodiment, the invention provides a moisture sensor, comprising: a capacitor that takes point capacitance measurements in concrete or a polymeric material and/or takes flux measurements in concrete or the polymeric material; such as, e.g., inventive moisture sensors wherein the capacitor is built into the concrete or the polymeric material; inventive moisture sensors wherein the capacitor comprises cement, a first electrode (such as, e.g., a steel mesh) and a second electrode (such as, e.g., a steel mesh); inventive moisture sensors comprising a porous material; inventive moisture sensors comprising a remote read-out device connected to the capacitor, wherein capacitance measurements are transmitted to the remote read-out device; etc.

Another preferred embodiment of the invention provides a construction method for a concrete structure or a polymeric structure, comprising: within the concrete or the polymeric material, constructing a point capacitance capacitor (such as, e.g., a capacitor comprising a porous material) into the concrete or polymeric material; such as, e.g., inventive construction methods including forming a quantity of cement paste, a first electrode (such as, e.g., a steel mesh) and a second electrode (such as, e.g., a steel mesh) in a capacitor configuration; inventive construction methods including forming a concrete structure; inventive construction methods including forming a polymeric structure; inventive construction methods including connecting a signal measurement device to the capacitor, and connecting the signal measurement to a read-out device; and other inventive construction methods.

### BRIEF DESCRIPTION OF THE DRAWINGS

FIG. 1 depicts a three-dimensional view of an exemplary embodiment of an inventive capacitor structure comprising a porous material, for use in an inventive moisture sensor.

FIG. 2 and FIG. 3 depict three-dimensional views of an exemplary embodiment of an inventive capacitor structure covered by a porous material, for use in an inventive moisture sensor.

FIG. 4 depicts a three-dimensional view of an exemplary embodiment of an inventive cylindrical capacitor structure comprising a porous material, for use in an inventive moisture sensor.

FIG. 5 depicts a three-dimensional view of the cylindrical capacitor structure of FIG. 4 further processed in a porous material base.

FIGS. 6A-6D, FIGS. 7A-7E are photographs of exemplary embodiments of inventive moisture sensors, showing cylindrical or oval shape sensors along with bare electrodes used to make the sensors.

FIG. 8 and FIG. 8A are respective block diagrams according to exemplary embodiments of the invention in which an inventive sensor is connected to a capacitance meter.

### DETAILED DESCRIPTION OF THE PREFERRED EMBODIMENT OF THE INVENTION

Inventive moisture-sensing methods and inventive moisture sensor devices. “Moisture” means the presence of water either in liquid or vapor phase. The “state of moisture” refers to whether moisture is “free” versus “bound.”

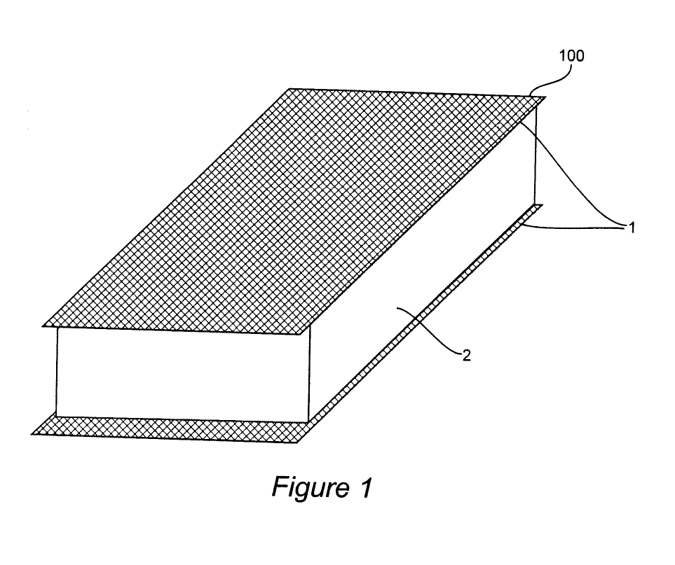

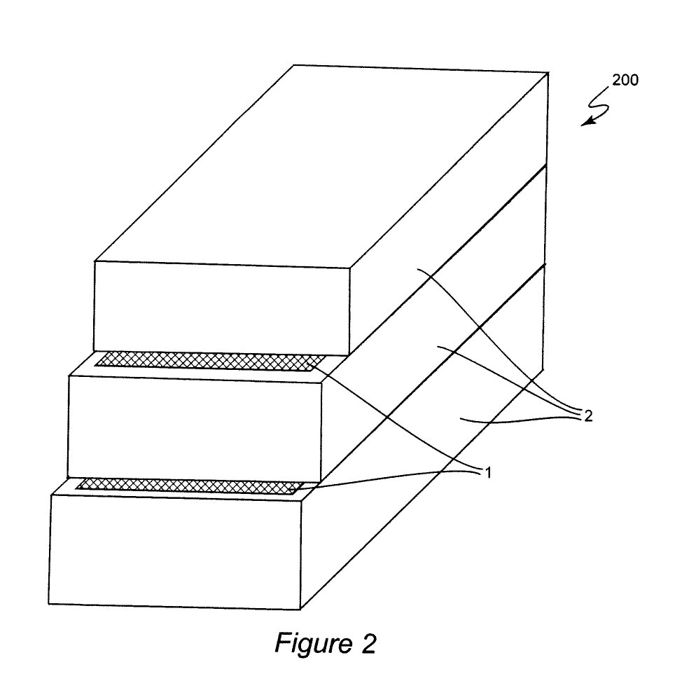

Referring, for example, to FIG. 1, the inventive moisture-sensing methods and inventive moisture sensor devices use a capacitor structure 100 comprising a pair of electrodes 1 (i.e., a pair of capacitance plates) and a porous material 2 (such as a cement paste, etc.) formed into a capacitor structure 100. For example, a first electrode placed parallel to a second electrode, with the porous material 2 between the parallel electrodes 1, forms a capacitor structure 100.

Examples of a pair of electrodes 1 useable in an inventive moisture sensor are, e.g., a pair of metal plates, a pair of wire meshes, etc. Wire mesh is particularly preferred for use as an electrode 1, because the wire mesh allows moisture to travel through the capacitor, thus reducing interference with the transport of moisture. It should be appreciated that in a pair of electrodes, the respective electrodes are not required to be identical and may differ in shape, thickness, material, etc. In the figures herein, even where the electrodes are shown using the same reference numeral, such as electrodes 1 in FIG. 1, the electrodes 1 are not required to be identical.

An example of a porous material 2 useable in an inventive moisture sensor is, e.g., cement paste (i.e., a paste made only with cement and water); concrete paste (i.e., concrete includes cement and aggregate mixed with water, also referred to as mortar in connection with using aggregate that is small in size). Cement paste is particularly suitable for use as the porous material when constructing a moisture sensor for use in concrete because cement paste has very similar properties to the paste found between aggregate in concrete. Cement paste can be altered to change the response time and sensitivity of a sensor in which it is used.

The porous material 2 useable in the inventive moisture sensor may be in a form of a matrix, such as a matrix which has changeable capacitance upon influx of a solvent. Examples of a matrix are, e.g., a polymer, wood, elastomer, soil, etc. For example, a polymer, wood, elastomer, soil, etc. may be used as the porous material in an inventive sensor, without requiring cement paste to be used. For constructing the thickness of the porous material 2, the considerations are response time, minimum and maximum capacitance values, physical dimensions, type of electrodes used and type of aggregate used in the paste. An example of a thickness of a porous material 2 which is a cement paste are, e.g., a thickness in a range of about 0.050 to 0.2 inches.

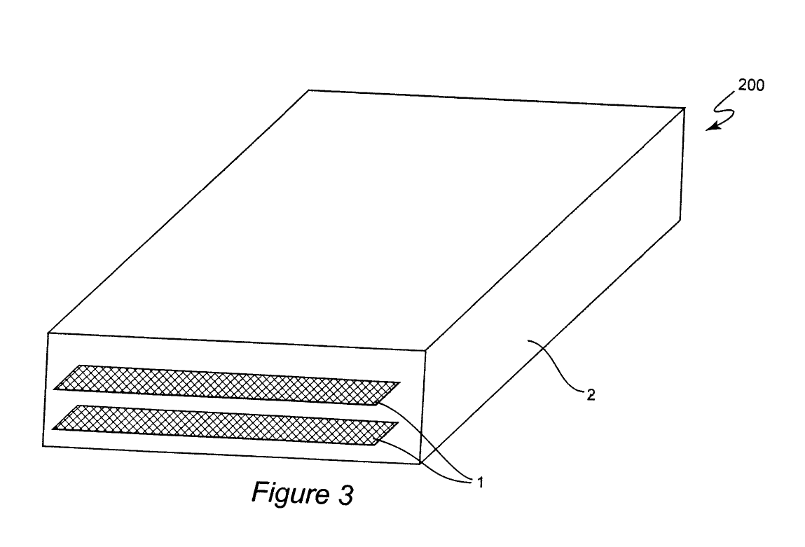

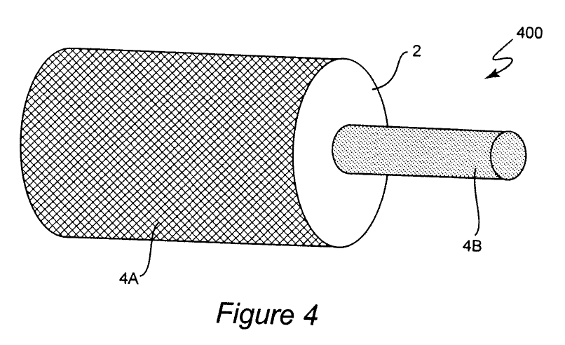

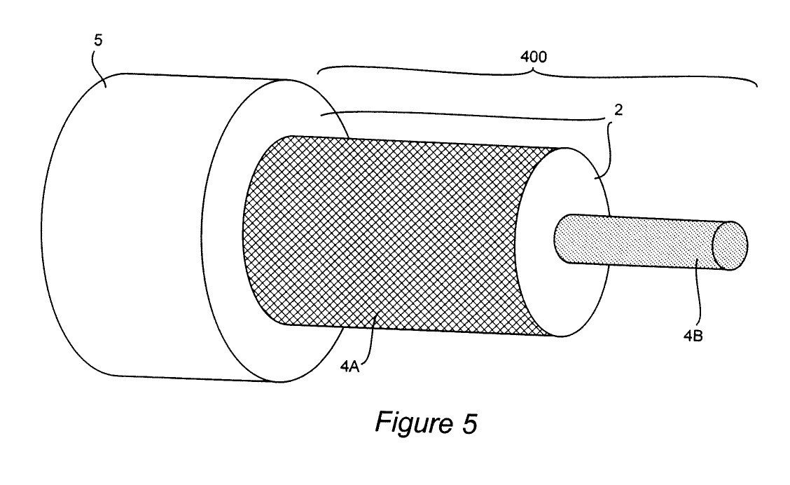

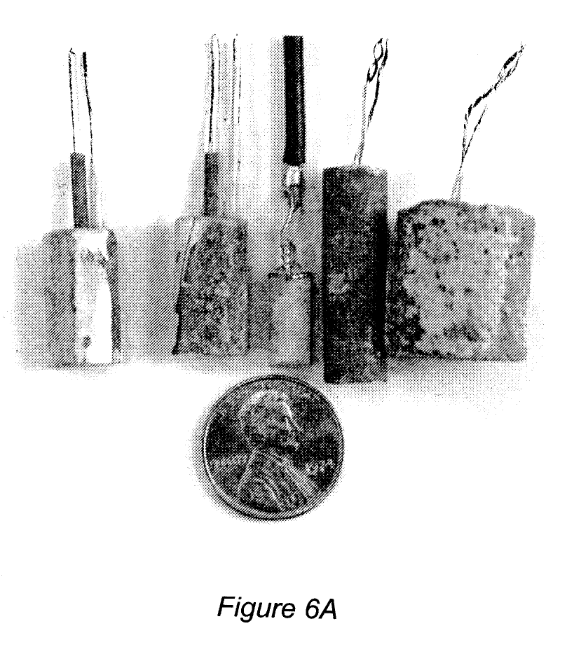

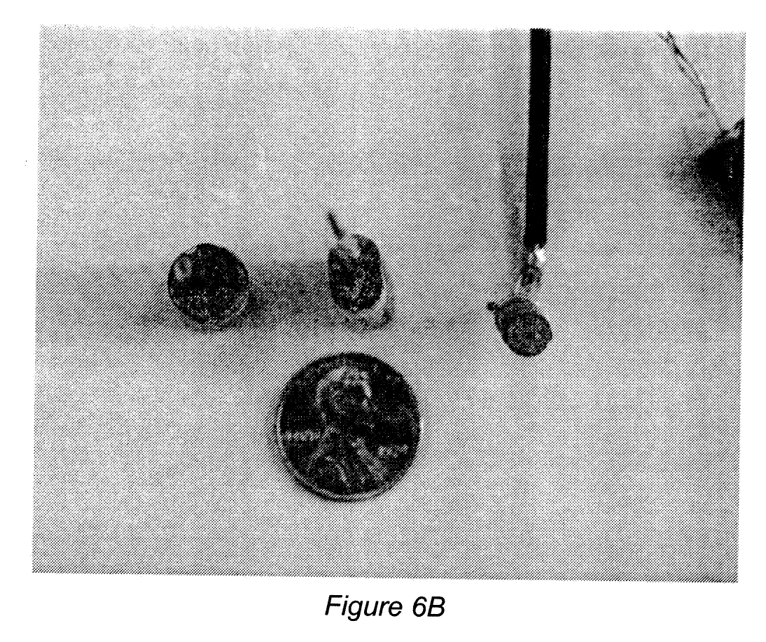

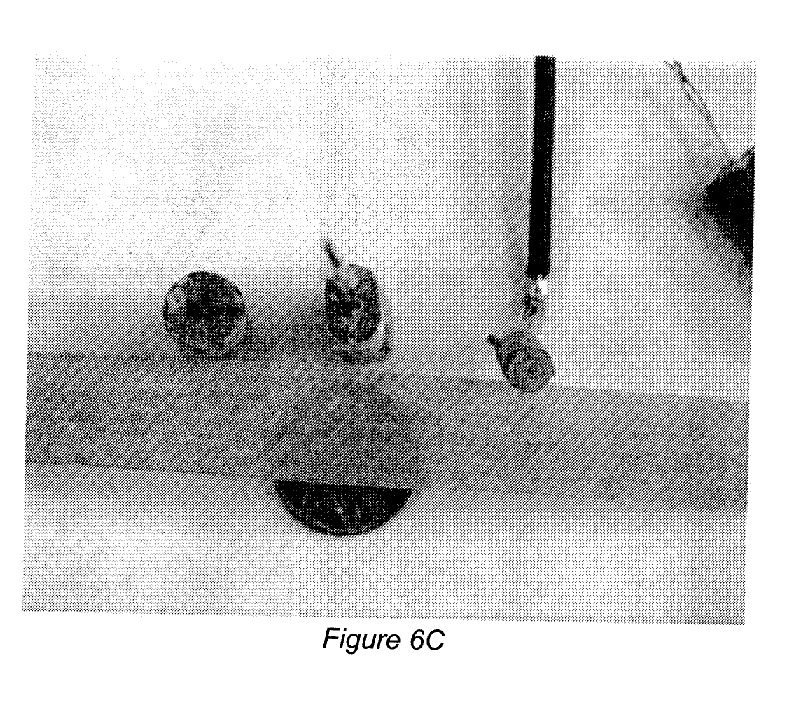

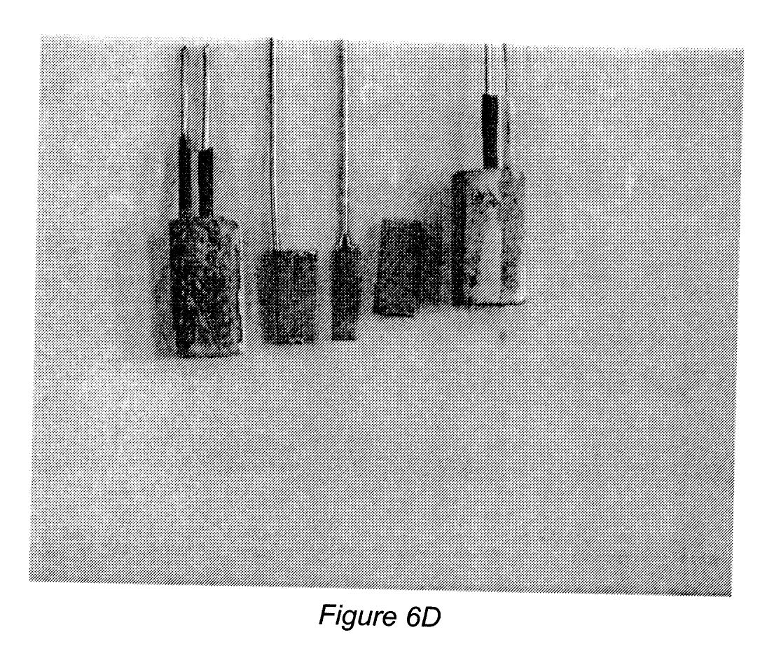

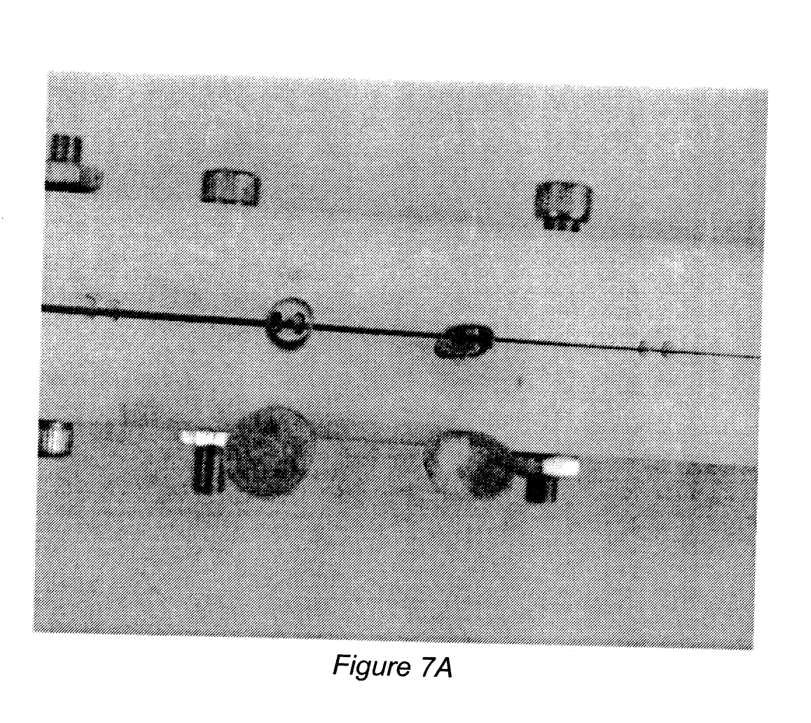

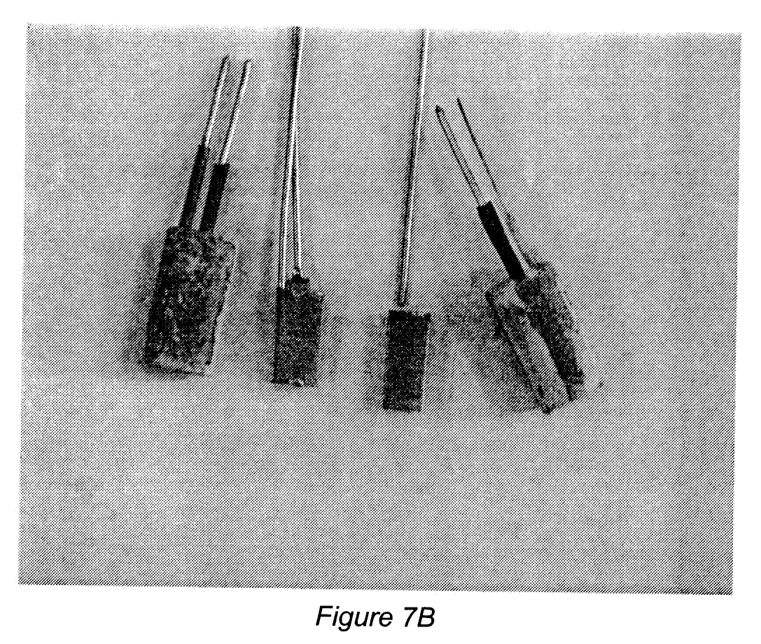

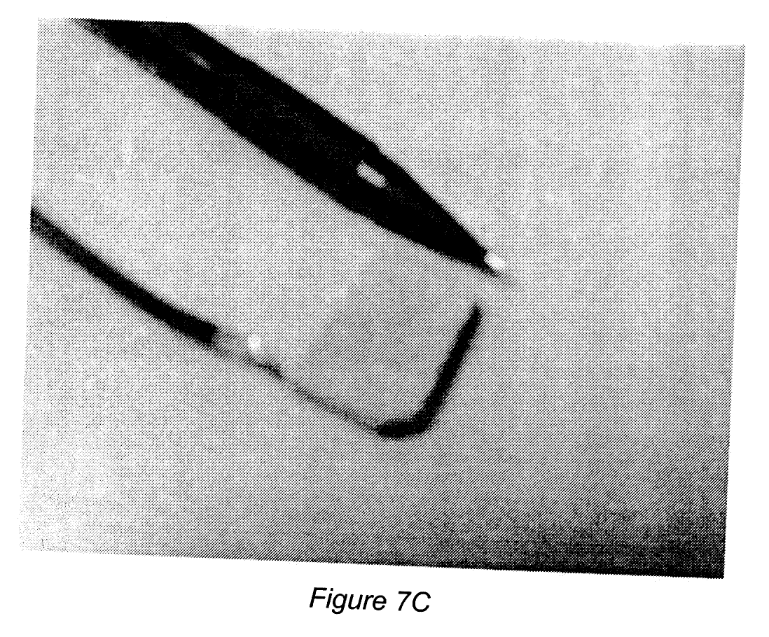

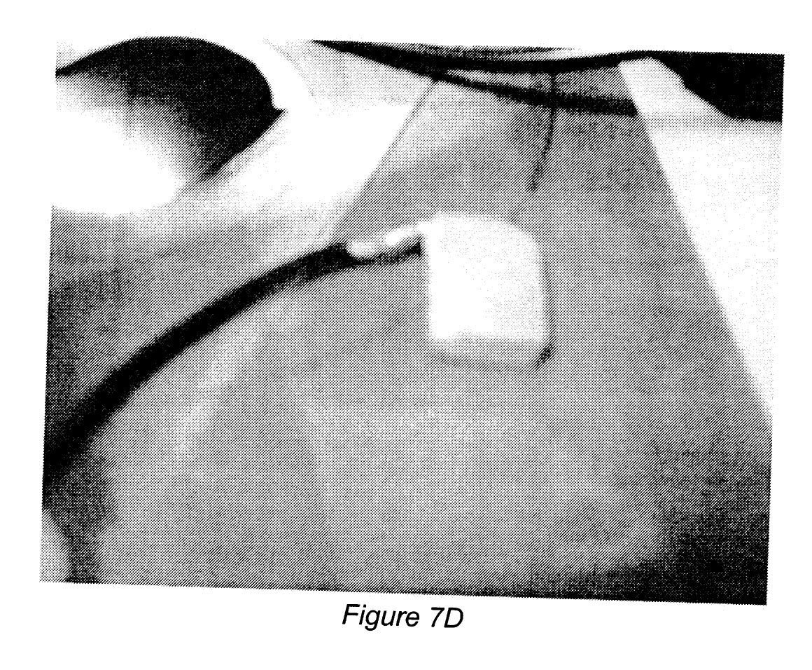

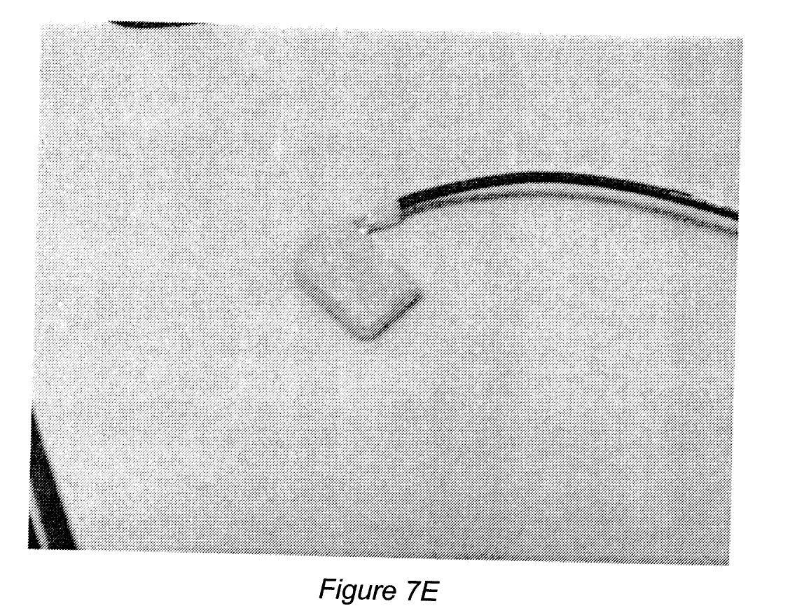

When constructing a capacitor structure for a moisture sensor for use in concrete, preferably a step is performed of applying concrete paste to the sensor surface to prevent the unnatural accumulation of moisture on the capacitance plates 1 (which would lead to inconsistent measurements in resistance and capacitance). The sensor surface to which this paste application is made is the surface of the sensor that is not bound between the two electrodes. In FIG. 1, the surface of the sensor is not coated while the surface of the sensors on FIG. 2 and FIG. 3 is covered with cement paste or concrete paste. Referring to FIG. 2, a capacitor structure 100 (FIG. 1) may be covered with porous material (such as, e.g., cement paste) to construct capacitor structure 200 (FIG. 2) comprising porous material 2. Another view of capacitor structure 200 is shown in FIG. 3. The surface of the sensor in FIG. 4 is not coated. The surface of the sensor on FIG. 5 is covered with cement paste or concrete paste.

Preferably a capacitor structure used in the invention is capable of making point measurements and/or flux measurements. “Point measurement” means a measurement that reflects the moisture at a single location at an instant in time. “Flux measurement” means the rate at which moisture moves through a surface. Point measurements and flux measurements according to the invention are contrasted with “bulk” measurements of capacitance. An example of a bulk measurement of capacitance is measuring water uptake by tracking the change in weight.

Size and geometry of a capacitor structure constructed for use in the invention can be varied to yield various characteristics, and to allow for point measurement, flux measurement, and/or measurements which are not hampered by gradient fields.

Another exemplary embodiment of an inventive capacitor structure for use in an inventive moisture sensor is a cylindrical capacitor structure, such as the cylindrical capacitor structure 400 in FIG. 4 comprising porous material 2 (such as, e.g., cement paste), electrode 4A (such as, e.g., wire mesh) outside the porous material 2 and in a shape of a cylindrical shell, and inner electrode 4B which is a central conductor. Inner electrode 4B may be, e.g., solid or wire mesh depending on size of the capacitor structure 400.

Referring to FIG. 5, the cylindrical capacitor structure 400 (FIG. 4) may be constructed into base 5 comprising a porous material (such as, e.g., cement paste).

An inventive moisture sensor comprising a capacitor structure comprising a porous material 2 may be constructed for use in, e.g., concrete, polymeric systems, submerged structures, etc. The inventive moisture sensors may be used for making moisture measurements in, e.g., concrete and concrete like materials that assist in the management of the concrete structures (such as, e.g., bridges, highway ramps, protective barriers, etc.).

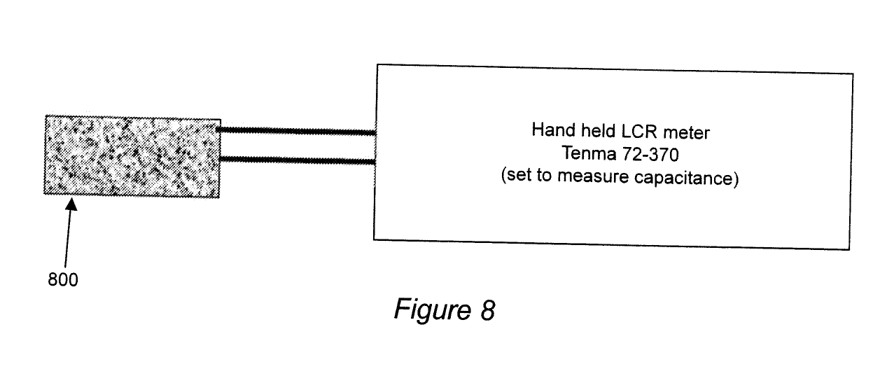

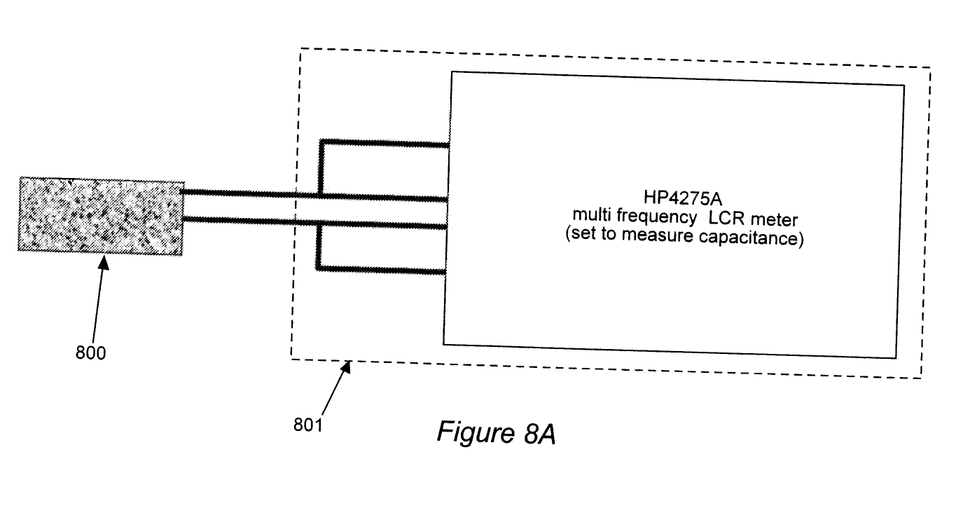

Referring to FIGS. 8-8A, for constructing a moisture sensor, an inventive sensor 800 comprising an inventive capacitor structure is connected (such as, e.g., by wiring) to a device reading capacitance. For reading capacitance from a capacitor structure, read-out devices are known, such as, e.g., HP4275A multi-frequency LCR meter; Fluke PM 6306 and PM 6304 RCL metters; Tenma 72-370; Bkprecision model 875B and 810C. The read-out device preferably is placed in a location for reading non-invasively, such as, e.g., on a external surface of a building, wall, etc. The read-out device may be placed relatively remotely from the capacitor structure. As shown in FIG. 8, the two wires of the sensor 800 can be connected to a capacitance meter using a coaxial cable to measure capacitance. Connecting the sensor to a hand held LCR meter is shown in FIG. 8. As shown in FIG. 8A, the two wires of the sensor can be connected to a capacitance meter using a coaxial cable to measure capacitance; there is used a system 801 comprising LCR meter with external wiring for 4-wire measurement.

The invention may be used to make moisture measurements in polymeric materials and composites, such as by providing a capacitor-based sensor including a polymer as the matrix material between the paired electrodes.

The inventive capacitor structures and inventive sensors may be used to provide information on moisture at any depth inside a concrete or polymeric material. The gradient moisture at the location of the sensor will affect the output, meaning that the sensor will give an average value over the volume of the sensor.

The invention also can be used for the measurement of moisture in soils, by using either cement paste or concrete paste as the matrix material.

Advantageously, inventive moisture sensors comprising an inventive capacitor structure comprising a porous material 2 may be feasibly operated in completely submerged conditions. For example, a preferred sensor is not affected if fully submerged in water and remains operational. An inventive sensor is preferred which does not need to be conditioned, even if the sensor experiences 100% condensing humidity.

Another advantage that may be provided by using an inventive sensor comprising a porous material is minimal effect on moisture diffusion.

The invention may be further appreciated with reference to the following Examples, without the invention being limited to the examples.

### EXAMPLE 1

An inventive sensor using solid metal plates for the electrodes 1 and cement paste for the porous material 2 was constructed according to FIG. 1 and tested. There was observed interference to diffusion, which was attributed to the solid metal plates.

### EXAMPLE 1A

An inventive sensor was constructed according to FIG. 1 in which, instead of solid metal plates as in Example 1, wire mesh was used for the electrodes 1. The wire mesh electrodes were oval, separated with cement paste. By using wire mesh (Example 1) instead of solid metal plates (Example 1A), the interference to diffusion was avoided.

The capacitor structures with parallel plates (Example 1), concrete cylinders and oval wire mesh electrodes separated with cement paste (Example 1A) were tested. In terms of capacitance measurements, all responded to change in humidity in surrounding environment.

### EXAMPLE 2

Referring to FIG. 2, an inventive capacitor structure 200 comprises electrodes 1 (such as wire mesh electrodes), and porous material 2 formed by coating the inventive capacitor structure 100 of FIG. 1 on the outside of the electrodes 1 with cement paste.

A capacitor structure was constructed according to FIG. 2 in which the electrodes 1 were wire mesh (Example 1A) and the outside of the electrodes 1 were coated with cement paste. The cement-coated capacitor structure 200 was tested and could be filly immersed in water without effects on performance.

### EXAMPLE 3

Cylindrical sensors ⅜ inches in diameter and ⅜×¼ oval (both ⅝ height) were made according to FIG. 4, and tested. Other larger sizes were made according to FIG. 4, and tested.

The capacitance of the cement-pasted sensors of Examples 2 and 3 were submerged in water, and permitted to stabilize, and the same capacitance readings were observed when the sensor was cycled between wet and dry environments. Capacitance readings were taken by HP4275A multi-frequency LCR meter. Capacitance readings in the dry environments were in a range of about 1 (one) to 7 (seven) Pico Farads. Capacitance readings in the wet environments were in a range of about 15 (fifteen) to 45 (forty-five) Pico Farads. These mentioned capacitance values depend highly on the paste used, and also on the frequency settings of the LCR meter.

While the invention has been described in terms of its preferred embodiments, those skilled in the art will recognize that the invention can be practiced with modification within the spirit and scope of the appended claims.

What we claim as our invention is:

1. A method of constructing a moisture sensor, comprising: into concrete or into a polymeric material that is to be measured for moisture, constructing a capacitor structure comprising a porous material.

2. The method of claim 1, wherein the capacitor structure constructing step is performed before the concrete is fully formed.

3. The method of claim 1, wherein the capacitor structure constructing step is after the concrete is formed.

4. The method of claim 1, wherein the constructing step includes providing a quantity of cement paste, a first electrode and a second electrode disposed together form a capacitor structure.

5. The method of claim 4, wherein the first electrode comprises a first stainless steel wire mesh and the second electrode comprises a second stainless steel wire mesh.

6. The construction method of claim 1, comprising: to the capacitor structure, connecting a read-out device where capacitance measures for the capacitor structure are readable.

7. The construction method of claim 1, including connecting a signal-measuring device to the capacitor structure, and connecting a read-out device to the signal-measuring device.

8. A method of sensing moisture in a concrete material or a polymeric material, comprising: in the concrete material or the polymeric material, making at least one point measurement of capacitance.

9. The moisture sensing method of claim 8, including making the least one point measurement of capacitance via a capacitor comprising a porous material, said capacitor being disposed within the concrete or the polymeric material.

10. The moisture sensing method of claim 9, wherein the capacitor within the concrete is remote from where the capacitance measurement is read.

11. The moisture sensing method of claim 8 wherein the point capacitance measurement is electrically transmitted to a remote device.

12. The method of claim 11, wherein the capacitor in the concrete or the polymeric material comprises a pair of stainless steel wire meshes.

13. The moisture sensing method of claim 8, wherein the concrete material or the polymeric material being sensed for moisture is submerged.

14. The moisture sensing method of claim 8, including expressing the point capacitance measurement as an electrical signal and transmitting the electrical signal to a read-out device.

15. A moisture sensor, comprising: a capacitor that takes point capacitance measurements in concrete or a polymeric material and/or takes flux measurements in concrete or the polymeric material.

16. The moisture sensor of claim 15, wherein the capacitor is built into the concrete or the polymeric material.

17. The moisture sensor of claim 15, wherein the capacitor comprises cement, a first electrode and a second electrode.

18. The moisture sensor of claim 17, wherein the first electrode is a first steel mesh and the second electrode is a second steel mesh.

19. The moisture sensor of claim 17, comprising a porous material.

20. The moisture sensor of claim 17, comprising a remote read-out device connected to the capacitor, wherein capacitance measurements are transmitted to the remote read-out device.

21. A construction method for a concrete structure or a polymeric structure, comprising: within the concrete or the polymeric material, constructing a point capacitance capacitor into the concrete or polymeric material.

22. The construction method of claim 21, wherein the capacitor comprises a porous material.

23. The construction method of claim 21, including forming a quantity of cement paste, a first electrode and a second electrode in a capacitor configuration.

24. The construction method of claim 23, wherein the first electrode comprises a first steel mesh and the second electrode comprises a second steel mesh.

25. The construction method of claim 21, including forming a concrete structure.

26. The construction method of claim 21, including forming a polymeric structure.

27. The construction method of claim 21, including connecting a signal measurement device to the capacitor, and connecting the signal measurement to a read-out device.
